(19) United States
(12) Patent Application Publication
(10) Pub. No.: US 2025/0358969 A1
(43) Pub. Date: Nov. 20, 2025

(54) TEMPERATURE CONTROL PLATE AND METHOD FOR PRODUCING A TEMPERATURE CONTROL PLATE

(71) Applicant: BENTELER AUTOMOBILTECHNIK GMBH, Paderborn (DE)

(72) Inventor: Elmar GRUSSMANN, Altenbeken (DE)

(21) Appl. No.: 18/949,923

(22) Filed: Nov. 15, 2024

(30) Foreign Application Priority Data
Nov. 16, 2023 (DE) 102023131965.5

(51) Int. Cl. H05K 7/20; B23K 3/04; B23K 101/36; B23K 103/10; H01M 10/613; H01M 10/6551

(52) U.S. Cl. CPC H05K 7/2039; B23K 3/04; H01M 10/613; H01M 10/6551; B23K 2101/36; B23K 2103/10

(57) ABSTRACT

A temperature control plate for battery cooling and a method for producing a temperature control plate. The temperature control plate has a plate body having first and second plate elements, and a connecting piece for a temperature control fluid. The connecting piece has an outer flange and a plug-in section, wherein the outer flange abuts an outside of the first plate element and the plug-in section is positioned in a mounting opening of the first plateelement. The mounting opening is in a formation in the first plateelement, wherein a circumferential edge of the mounting opening is displaced relative to a plate plane of the first plateelement. An end section of the plug-in section is formed into an inner flange, wherein an annular groove is formed between the outer and inner flanges, and the circumferential edge of the mounting opening lies in the annular groove.

### RELATED APPLICATIONS

The present application claims priority of German Application Number 10 2023 131 965.5 filed Nov. 16, 2023, the disclosure of which is hereby incorporated by reference herein in its entirety.

### FIELD

The present disclosure relates to a temperature control plate for the temperature control of electronic components and/or batteries and to a method for producing temperature control plates, and a cooling plate for battery cooling, for example, cooling a battery of motor vehicles.

### BACKGROUND

High-voltage battery systems are used in electric or hybrid vehicles. Thermal management of the batteries ensures the range, driving performance, and charging performance as well as the service life of electrically driven vehicles. In order to keep the batteries within an optimal temperature range, temperature control devices are used to ensure that excess waste heat arising when the batteries are operated is discharged from the batteries and the batteries are kept at a uniform temperature level.

For the temperature control of batteries or battery modules, temperature control plates are used which contact the batteries directly or indirectly. A temperature control fluid flows through the temperature control plates. Such temperature control plates include two plate elements which, when assembled to form a plate body, delimit one or more interposed channels. The temperature control fluid is guided through the channel or channels. The temperature control plates are manufactured from light metal sheets, for example, aluminum sheets.

In order to supply and discharge the temperature control fluid to and from the temperature control plates, the plates are provided with connecting pieces. The connecting pieces are manufactured by shaping or machining. The connecting pieces are fastened on a temperature control plate via material bonding by welding, soldering, or adhesive bonding. Screw connections are also used.

The fixing of the connecting pieces after the plate body of a temperature control plate has been produced utilizes an additional joining step and is correspondingly complicated.

Temperature control plates in the form of cooling plates are also utilized.

A soldered cooling plate formed from a structural plate and a cover plate is described in DE 10 2014 217 728 A1.

A cooling plate and a method for producing a cooling plate are described in DE 10 2008 059 955 B4. The cooling plate has a connecting piece for a cooling fluid, wherein the connecting piece has a mounting flange and a plug-in section. The mounting flange abuts the plate body of the cooling plate. The plug-in section is positioned in a mounting opening of the plate body and is plastically deformed and joined to the plate body.

Possible leaks are problematic in the case of material bonds between the temperature control plate or cooling plate and the connecting pieces, for example, as a result of thermal warping and the associated finishing expenditure.

### SUMMARY

The present disclosure is based on the object of providing a temperature control plate improved with respect to function and production, having an efficiently and reliably joined connecting piece, as well as describing a method for producing such a temperature control plate.

The part of the object according to the subject matter is achieved by a temperature control plate.

A temperature control plate has a plate body formed from two plate elements. A temperature control fluid is supplied and discharged via connecting pieces. The connecting pieces are joined with the plate body or its plate elements by material bonding. The plate elements are able to be a channel plate and a base plate, which are brought together to form a plate stack and joined together to form the plate body. The plate elements are made of light metal or a light metal alloy, for example, an aluminum alloy. At least one plate element of the plate body of the temperature control plate has a channel structure for conducting through a temperature control fluid. The plate elements are joined via material bonding by means of press soldering. The soldering process is carried out in a forming soldering tool. A plate stack formed from the two plate elements is clamped in the forming soldering tool, pressed against one another, and heated to a temperature above the melting temperature of the solder material applied between the plate elements, so that the solder material enters a liquid phase by melting, and after the solder material has solidified, a material bond of the plate elements is formed at the adjacent joining surfaces.

To form one or more channels in at least one of the plate elements, the plate elements are clamped in a forming soldering tool and a space between the plate elements is subjected to internal pressure. For this purpose, an active medium is conducted into the space and a channel structure having at least one channel or multiple channels is created by hydroforming.

The connecting piece of a temperature control plate according to the present disclosure has an outer flange and a plug-in section. The outer flange abuts the outside of a plate element of the plate body of the temperature control plate. The plug-in section is positioned in a mounting opening of the plate element and is plastically deformed. According to the present disclosure, the mounting opening is arranged in a formation in the first plate element. A circumferential edge of the mounting opening is displaced in relation to the plate plane of the first plate element by the formation. The plug-in section of the connecting piece is inserted through the mounting opening in the plate element. An end section of the plug-in section is formed by plastic deformation into an inner flange. The inner flange extends radially outwards in a circumferential manner. An annular groove is formed between the outer flange and the inner flange. The edge of the mounting opening extends in the annular groove. The circumferential edge of the mounting opening is joined between the outer flange and the inner flange in a form-fitting and fluid-tight manner. The flanging of the end section forms the inner flange and creates a crimped connection between the connecting piece and the first plate element.

The mounting opening and the diameter of the plug-in section are configured to match one another. The mounting opening is able to be embodied round, oval, or like an elongated hole. The mounting opening is produced by stamping in the first plate element. The mounting opening is able to be introduced into the first plate element before the formation is produced, during the production of the formation, or after the formation is produced.

The connecting piece is firmly connected to the plate element by the crimped connection. The plate element is able to be supplied for further use and forms the first plate element of a plate stack for producing a plate body of a temperature control plate.

The plate elements are joined to one another and at least one plate element and the connecting piece or the connecting pieces are joined to one another by material bonding, for example, by soldering, or by press soldering.

The formation is designed as a local depression in a plate element. The formation is configured in the shape of a cup or shell. The depression is able to have a round, oval, or elongated circumference. The depth of the formation is small in relation to the smallest diameter of the formation. The formation has a circumference and a depth which are dimensioned such that the inner flange is accommodated in the formation.

In at least one embodiment of the present disclosure, the wall thickness of the inner flange is advantageously dimensioned between greater than or equal to 0.5 mm and less than or equal to 1.0 mm.

In at least one embodiment of the present disclosure, the formation has a depth that is greater than or equal to the wall thickness of the inner flange. In at least one embodiment of the present disclosure, the formation is geometrically dimensioned such that the inner flange is accommodated in the receptacle and is flush with the adjacent inner surface of the first plate element. The inner flange does not protrude relative to the inner surface of the first plate element. Flush means that the inner side of the inner flange and the inner surface of the first plate element terminate at the same height, taking into consideration component tolerances.

In at least one embodiment of the present disclosure, a solder material, for example, a ring made of solder material, i.e., a solder ring and/or a seal, is incorporated between the outer flange and the first plate element. The solder material or the solder ring is also able to form the seal. The solder material melts during the press-soldering joining of the plate elements and the connecting piece. After the solder has solidified, a material bond is produced between the outer flange and the circumferential edge of the mounting opening clamped between the outer flange and the inner flange.

Furthermore, the solder material, for example, the solder ring, and/or the seal is advantageously arranged in a receptacle in the outer flange. This results in a second form-fitting and fluid-tight connection.

A method for producing a temperature control plate includes the following steps:
providing a connecting piece, which has an outer flange and a plug-in section;
providing a first plate element;
forming a formation in the first plate element and producing a mounting opening in the first plate element,
wherein, during the formation of the formation, a bottom of the formation and/or a circumferential edge of the mounting opening is displaced in relation to the plate plane of the first plate body;
inserting the plug-in section into the mounting opening until the outer flange abuts the first plate element;
forming an end section of the plug-in section into an inner flange,
wherein an annular groove is formed between the outer flange and the inner flange and the edge of the mounting opening is fixed in the annular groove between the outer flange and the inner flange;
providing a second plate element and forming a plate stack from the first plate element and the second plate element, wherein a solder material is or will be applied between the plate elements;
inserting the plate stack into a heated forming soldering tool, which has a lower tool and an upper tool;
closing the forming soldering tool and clamping the plate stack between the lower tool and the upper tool;
heating the plate stack;
subjecting a space between the plate elements of the plate stack to internal pressure by introducing an active medium into the space and forming a channel in at least one plate element;
melting the solder material between the plate elements and soldering the plate elements on joining surfaces in contact and soldering the connecting piece with the first plate element;
opening the forming soldering tool and removing the temperature control plate from the forming soldering tool.

The production of the local formation in the first plate element and the production of a mounting opening is able to be carried out in parallel or offset in time relative to one another. First, the formation is able to be formed in the form of a local recess or pre-embossing in an area of the first plate element and then a mounting opening is able to be stamped in the formation or in the bottom of the formation. However, the shaping and the mounting opening are able to be produced chronologically in parallel. A mounting opening is also able to be produced first in the plate element and then the area around the mounting opening is able to be formed and the formation is able to be produced by forming.

A bottom of the formation and/or a circumferential edge of the mounting opening is displaced in relation to the plate plane of the first plate body by the formation. The edge of the mounting opening then extends, for example, retracted in an S-shape. The connecting piece is inserted with its plug-in section into the mounting opening until the outer flange abuts the first plate element.

The end section of the plug-in connector is then plastically deformed and an inner flange is formed.

The inner flange on the plug-in section is formed radially outwards circumferentially. In at least one embodiment of the present disclosure, the inner flange is oriented at an angle of 90° to the longitudinal axis of the connecting piece. The edge of the mounting opening is accommodated in a form-fitting and fluid-tight manner in the annular groove formed between the outer flange and the inner flange.

The forming of the end section on the plug-in section takes place in two stages. In a first forming stage, the end section is formed or bent outwards. In this case, the end section is bent at an angle of approximately 45° to the longitudinal axis of the connecting piece. In a second forming stage, the end section is radially repositioned, at an angle of approximately 90° to the longitudinal axis of the connecting piece.

A crimped connection results between the outer flange and the inner flange and the edge of the mounting opening extending between them in the annular groove by plastic deformation of the joining partners, for example, the inner flange.

The plate elements are materially bonded to one another in a forming soldering tool. In the forming soldering tool, the connecting piece is also connected to the first plate element by soldering.

The forming soldering tool is heated to a tool temperature at which both the hydroforming process to form the channel and the joining process by soldering are carried out. In at least one embodiment of the present disclosure, the tool temperature is between 540° C. and 670° C., the tool temperature is between 550° C. and 640° C.

In order to produce a temperature control plate, a plate stack is formed which includes a first plate element and a second plate element. The plate elements include a metallic material, for example, a light metal alloy. A solder material is applied between the plate elements or the solder material is applied during the formation of the plate stack. At least the first plate element has a connecting piece joined thereto according to the present disclosure. The plate stack is placed in the heated forming soldering tool. This forming soldering tool has a lower tool and an upper tool. The forming tool is closed, wherein the lower tool and the upper tool are displaced relative to one another.

In at least one embodiment of the present disclosure, the closing process of the forming soldering tool is interrupted before reaching the closed position. The upper tool and the lower tool are kept at a distance from one another in this holding position with the plate stack inserted. The holding position is maintained for a holding time. At this time, the plate stack resting on the lower tool is heated. After the holding time, the closing movement is continued, the forming soldering tool is closed, and the plate stack is clamped between the lower tool and the upper tool. Clamped in the forming soldering tool, the plate stack is heated up further to the soldering temperature. To form one or more channels in at least one of the plate elements, a space between the plate elements clamped in the forming soldering tool is subjected to internal pressure. For this purpose, an active medium is conducted into the space and a channel structure having at least one or multiple channels is created by hydroforming. The active medium is able to be introduced into a space between the plate elements via the connecting piece, which has previously been joined in a form-fitting and fluid-tight manner.

After opening the forming soldering tool and, if necessary, a cooling phase, the temperature control plate is able to be removed from the soldering tool.

### BRIEF DESCRIPTION OF THE DRAWINGS

The present disclosure is described in more detail hereinafter on the basis of drawings. In the figures:

FIG. 1 shows a section of a temperature control plate with a perspective view of a connecting piece according to at least one embodiment;

FIG. 2 shows a section of a panel element with a top view of a mounting opening according to at least one embodiment;

FIG. 3 shows a section through the representation of FIG. 2 along line A-A after the production of a formation according to at least one embodiment;

FIG. 4 shows a cross-sectional view of a connecting piece according to at least one embodiment;

FIG. 5 shows a section through a first plate element of a temperature control plate and a connecting piece connected thereto according to at least one embodiment;

FIG. 6 shows a forming tool with the representation of a first forming stage for fixing a connection piece in an assembly opening of a first plate element according to at least one embodiment; and

FIG. 7 shows a forming tool with the representation of a second forming stage for fixing a connection piece in an assembly opening of a first plate element according to at least one embodiment.

### DETAILED DESCRIPTION

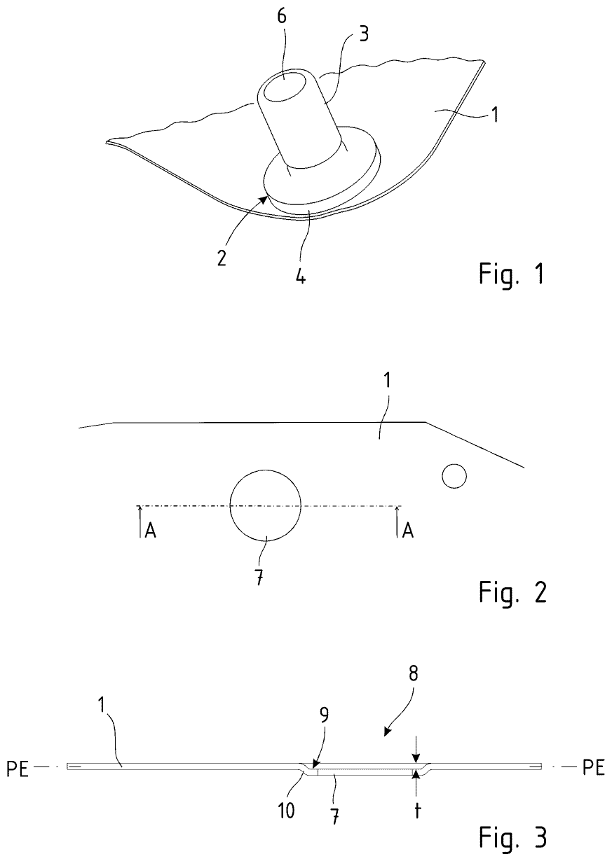

FIG. 1 shows a section of a first plate element 1 of a temperature control plate and a connection piece 2 fixed on the plate element 1.

A temperature control plate is used for battery cooling, for example, for a vehicle battery of a motor vehicle. A temperature control plate has a plate body formed from two plate elements. The first plate element 1 of the plate elements is shown here. In at least one embodiment of the present disclosure, a temperature control plate has two connecting pieces 2 for the supply and the discharge of temperature control fluid. The first plate element 1 shown here is a completely or nearly completely flat base plate. The plate body of the temperature control plate is completed by a second plate element, which is a channel plate including a channel structure having at least one temperature control channel.

The first plate element 1 and the second plate element are positioned flat one on top of another and form the plate body. The abutting surfaces of the plate elements are provided with a solder material completely or in some areas. In at least one embodiment of the present disclosure, a solder material in the form of a plated solder layer is preapplied to one of the plate element. The abutting surfaces of the plate elements are joined with one another completely or in some areas. The connecting piece 2 is joined to the first plate element 1 in a form-fitting and materially-bonded manner.

The connecting piece 2 has an outer connecting section 3. This is configured for connecting a temperature control fluid line. Furthermore, the connecting piece has an outer flange 4 extending radially outwards from the connecting section 3 (see FIG. 4 in this respect). As an extension of the connecting section 3, the connecting piece 2 has a plug-in section 5. A through opening 6 extends through the connecting piece 2 in its longitudinal direction.

A mounting opening 7 is introduced into the first plate element 1 (see FIG. 2 and FIG. 3 in this regard). In the illustrated exemplary embodiment, the mounting opening 7 is round. The mounting opening 7 has a diameter which is matched to the outer diameter of the plug-in section 5.

The mounting opening 7 is arranged in a formation 8 of the first plate element 1. The formation 8 is formed by a local depression 9 in the first plate element 1. The mounting opening 7 has a circumferential edge 10. The edge 10 is configured curved in an S-shape. The edge 10 of the mounting opening 7 is displaced in one direction in relation to the plate plane PE of the first plate element 1. The forming for this purpose is shear forming or compression forming.

The outer flange 4 has a receptacle 12 in the form of a circumferential groove on its flange side 11 facing toward the plate element 1. A solder material in the form of a solder ring 13 is accommodated in the receptacle.

The connecting piece 2 is fixed on the first plate element 1. This is achieved in a form-fitting manner by a plastic deformation of an end section 14 of the plug-in section 5. The end section 14 is flanged for this purpose and a crimped connection is produced.

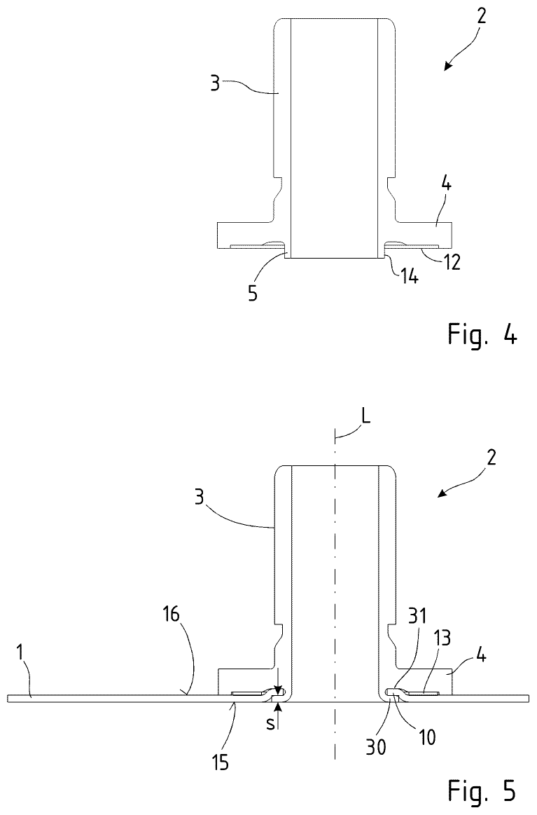

The illustration of FIG. 5 shows a connecting piece 2 that is connected in a form-fitting manner to the first plate element 1.

To mount the connecting piece 2 on the first plate element 1, the connecting piece 2 is inserted with its plug-in section 5 into the mounting opening 7 until the outer flange 4 abuts the outside of the first plate element 1. The plug-in section 5 then projects in the longitudinal direction of the connecting piece 2 relative to an inner surface 15 of the first plate element 1. The flange side 11 and the solder ring 13 positioned in the receptacle 12 circumferentially abut an outer surface 16 of the first plate element 1 adjacent to the formation 8.

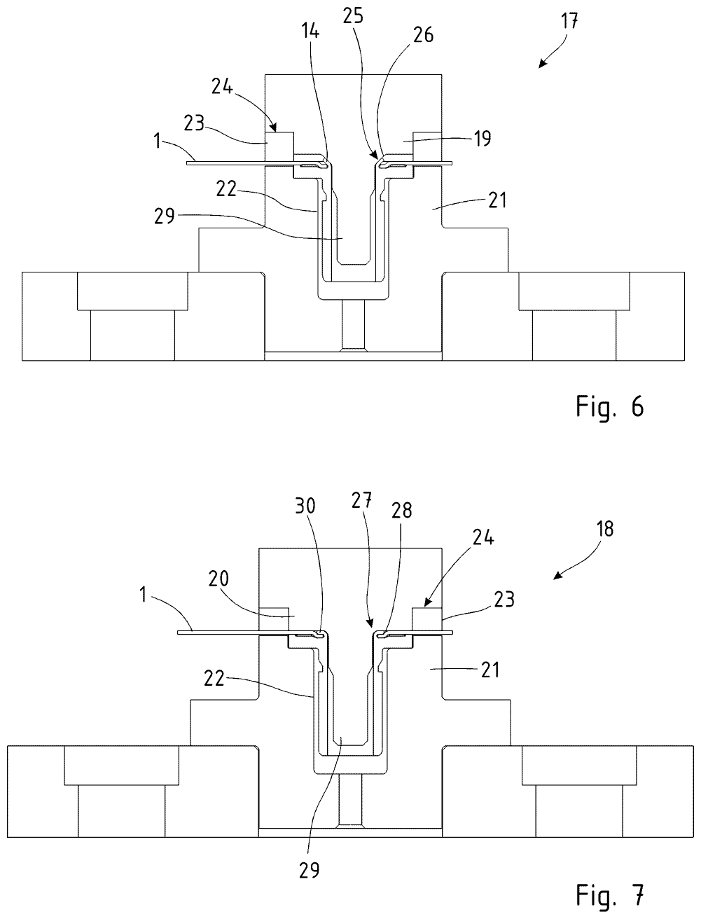

The form-fitting crimping of the connecting piece 2 with the first plate element 1 takes place in two stages. The joining process is explained using FIG. 6 and FIG. 7.

The first forming stage is shown in FIG. 6.

The second forming stage is shown in the illustration of FIG. 7.

The flanging process and the production of the crimped connection between the connecting piece and the first plate element 1 takes place in two forming tools 17, 18, which are constructed in the same way and differ only in the shaping contour of their male die 19 and 20, respectively.

The first forming tool 17 is shown in FIG. 6.

FIG. 7 shows the second forming tool 18.

A forming tool 17, 18 has an upper male die 19 or 20, a counterholder 21 with a connector receptacle 22 as well as a hold-down device 23 and an upper damper element 24 arranged in the hold-down device 23.

To produce the clinched connection between the connecting piece 2 and the first plate element 1, the plate element 1 is positioned in the first forming tool 17, with the plug-in section 5 of the connecting piece 2 inserted into the mounting opening 7. The connecting piece 2 projects with its connecting section 3 into the connector receptacle 22. The plug-in section 5 protrudes axially in the longitudinal direction of the connecting piece 2 in the direction of the male die 19. The first plate element 1 is clamped between the counterholder 21 and the hold-down device 23 and the male die 19 is displaced axially. The male die 19 is lowered in the direction of the end section 14. This is achieved by applying an external axial force. The male die 19 has a forming contour 25 which comes to rest on the inside of the end section 14 of the plug-in section 5 during the axial displacement of the male die 19. The forming contour has an inclined surface 26 extending at an angle of approximately 45°. The latter comes to rest on the end section 14. The inclined surface 26 acts as a wedge and transmits a radial force to the end section 14, so that the latter is bent outwards relative to the longitudinal axis L of the connecting piece 2. This is shown in FIG. 6. The end section 14 is bent outwards at an angle of approximately 45° to the longitudinal axis L of the connecting piece 2.

The components, i.e. the first plate element 1 and the connecting piece 2 pre-fixed on the first plate element 1, are then transferred into the second forming tool 18. The male die 20 of the second forming tool 18 has a forming contour 27 which is configured and intended to fold over or flange the end section 14 of the plug-in section 5, which end section is bent outwards in the first forming stage, at a right angle. For this purpose, the forming contour 27 has a forming surface 28 oriented at a right angle to the longitudinal axis L of the connecting piece 2. By lowering the male die 20, the end section 14 is formed at a right angle, for example, at an angle of approximately 90° to the longitudinal axis L of the connecting piece 2, and the components are crimped with one another. This is shown in the illustration of FIG. 7.

Both the shaping tool 17 and the shaping tool 18 have a mandrel 29 which projects in extension of the male die 19 and 20 and protrudes into the through opening 6 of the connecting piece 2. As a result, the connecting piece 2 is supported on the inside, for example, on the inner circumference of the through opening 6, in the area of the outer flange 4 and of the plug-in section 5. The mandrel 29 is able to act as a height or travel limiter in conjunction with an inner stop. In at least one embodiment of the present disclosure, the axial displacement travel of the male dies 19, 20 is limited by a stop which rests on the front side of the mandrel 29.

The end section 14 of the plug-in section 5 is formed into an inner flange 30 directed radially outward from the connecting piece 2 (see also FIG. 5 in this respect).

An annular groove 31 is formed between the outer flange 4 and the inner flange 30 of the connecting piece 2. The circumferential edge 10 of the mounting opening 7 is accommodated in the annular groove 31 and is joined by crimping between the outer flange 4 and the inner flange 30 in a fluid-tight and form-fitting manner.

The inner flange 30 has a wall thickness s. The formation 8 has a depth t. The depth t of the formation 8 is dimensioned greater than or equal to the wall thickness s of the inner flange 30. The formation 8 is geometrically configured such that the inner flange 30 is accommodated in the formation 8 or the recess 9 and terminates flush with the adjacent inner surface 15 of the first plate element 1.

The wall thickness s is between 0.5 mm and 1.0 mm inclusive. The depth t of the formation 8 is dimensioned accordingly. In at least one embodiment of the present disclosure,, the depth t of the formation 8 and the wall thickness s of the inner flange 30 correspond to one another and are dimensioned similarly, so that laminar flow conditions exist in the transition area when a temperature control fluid flows through.

The first plate element 1 with the connecting piece 2 joined thereon is then supplied to the further production process for producing a temperature control plate. The first plate element 1 is combined with a second plate element to form a plate stack. At least one of the two plate elements is provided with a solder material, for example, with a plated solder material layer. The plate stack of the two plate elements is clamped in a forming soldering tool. In at least one embodiment of the present disclosure, the forming soldering tool is closed and the plate stack is clamped between the lower tool and the upper tool of the forming soldering tool. In the forming soldering tool, the plate stack is heated to a temperature above the melting temperature of the solder material. Clamped in the forming soldering tool 15, 16, an active medium is introduced into a space between the plate elements and a channel structure having at least one channel is produced by hydroforming. The active medium is able to be supplied via the connecting piece 2. In the forming soldering tool, the solder ring 13 positioned in the receptacle 12 is also melted, so that the solder ring enters a liquid phase. After the solder material has solidified, a materially-bonded connection is created between the plate elements and between the first plate element 1 and the connecting piece 2 at the adjacent joining surfaces.

The foregoing description of some embodiments of the disclosure has been presented for purposes of illustration and description. The description is not intended to be exhaustive or to limit the disclosure to the precise form disclosed, and modifications and variations are possible in light of the above teachings. The specifically described embodiments explain the principles and practical applications to enable one ordinarily skilled in the art to utilize various embodiments and with various modifications as are suited to the particular use contemplated. Various changes, substitutions and alterations can be made hereto without departing from the spirit and scope of the disclosure.

1-14. (canceled)

15. A temperature control plate for the temperature control of electronic components or batteries, the temperature control plate comprising:
a plate body which has a first plate element and a second plate element;
at least one connecting piece for a temperature control fluid, wherein the at least one connecting piece joins together the first plate element and the second plate element,
the at least one connecting piece has an outer flange and a plug-in section, wherein the outer flange abuts an outside of the first plate element, and the plug-in section is positioned in a mounting opening of the first plate element which comprises an end section of the plug-in section, wherein the mounting opening is arranged in a formation in the first plate element,
wherein a circumferential edge of the mounting opening is displaced in relation to a plate plane of the first plate element and the end section comprises an inner flange,
wherein an annular groove is between the outer flange and the inner flange and the circumferential edge is accommodated in the annular groove.

16. The temperature control plate according to claim 15, wherein the inner flange has a wall thickness and the formation has a depth, wherein the depth of the formation is dimensioned to be greater than or equal to the wall thickness of the inner flange.

17. The temperature control plate according to claim 15, wherein the formation is geometrically dimensioned so the inner flange is accommodated therein and ends of the inner flange are substantially flush with an adjacent inner surface of the first plate element.

18. The temperature control plate according to claim 15, wherein a solder material is incorporated between the outer flange and the first plate element.

19. The temperature control plate according to claim 18, wherein the solder material is arranged in a receptacle in the outer flange.

20. The temperature control plate according to claim 15, wherein the first plate element and the second plate element or the at least one connecting piece comprises a light metal material.

21. A method of producing a temperature control plate having a connecting piece, the comprising:
forming a formation in a first plate element and producing a mounting opening in the first plate element, wherein, during the forming of the formation, a bottom of the formation or a circumferential edge of the mounting opening is displaced in relation to a plate plane of the first plate element;
inserting a plug-in section of a connecting piece into the mounting opening until an outer flange of the connecting piece abuts the first plate element;
forming an end section of the plug-in section into an inner flange, wherein an annular groove is formed between the outer flange and the inner flange and the circumferential edge of the mounting opening is fixed in the annular groove between the outer flange and the inner flange;
forming a plate stack from the first plate element and the second plate element, wherein a solder material is appliable between the first plate element and the second plate element;
inserting the plate stack into a heat forming soldering tool, which has a lower tool and an upper tool;
closing the heat forming soldering tool and clamping the plate stack between the lower tool and the upper tool;
heating the plate stack;
subjecting a space between the first plate element and the second plate element to internal pressure by introducing an active medium into the space and forming a channel in at least one plate element of the first plate element or the second plate element;
melting the solder material between the first plate element and the second plate element, and soldering the first plate element and the second plate element on joining surfaces in contact and soldering the connecting piece with the first plate element; and
opening the heat forming soldering tool and removing the temperature control plate from the heat forming soldering tool.

22. The method according to claim 21, wherein the inner flange is formed radially outward circumferentially on the plug-in section.

23. The method according to claim 21, wherein the formation in the first plate element is geometrically dimensioned so the inner flange lies in a receptacle in the outer flange at ends substantially flush with an adjacent inner surface of the first plate element.

24. The method according to claim 21, wherein the forming of the end section on the plug-in section is performed in two stages, wherein in a first forming stage of the two stages an end section is bent outwards at an angle of approximately 45° to a longitudinal axis of the connecting piece, and in a second forming stage of the two stages the end section is radially repositioned at an angle of approximately 90° to a longitudinal axis of the connecting piece.

25. The method according claim 21, wherein the circumferential edge of the mounting opening is joined in the annular groove between the outer flange and the inner flange in a form-fitting and fluid-tight manner.

26. The method according to claim 21, wherein a solder material is incorporated between the outer flange and the first plate element.

27. The method according to claim 21, wherein the heat forming soldering tool is heated to a tool temperature between 540° C. and 670° C.

28. The method according claim 21, wherein the closing of the forming soldering tool is interrupted before reaching a closed position for a holding time, wherein the upper tool and the lower tool are kept at a distance to one another with the plate stack inserted and the heat forming soldering tool is closed after the holding time and the plate stack is clamped between the lower tool and the upper tool.

29. The temperature control plate according to claim 18, wherein the solder material comprises a solder ring or a seal.

30. The temperature control plate according to claim 15, wherein the first plate element and the second plate element or the at least one connecting piece comprises an aluminum alloy.

31. The method according to claim 21, wherein the heat forming soldering tool is heated to a tool temperature between 550° C. and 640° C.
